(19) United States
(12) Patent Application Publication
(10) Pub. No.: US 2022/0098740 A1
(43) Pub. Date: Mar. 31, 2022

(54) CO2 REDUCTION INTO SYNGAS

(71) Applicant: The Regents of the University of Michigan, Ann Arbor, MI (US)

(72) Inventors: Zetian Mi, Ann Arbor, MI (US); Sheng Chu, Montreal (CA); Pengfei Ou, Montreal (CA); Jun Song, Montreal (CA)

(21) Appl. No.: 17/619,473

(22) PCT Filed: Jun. 17, 2020
(86) PCT No.: PCT/US2020/038082

§ 371 Date: Dec. 15, 2021

Related U.S. Application Data
(60) Provisional application No. 62/862,332, filed on Jun. 17, 2019.

(51) Int. Cl. C25B 11/052; C23C 16/455; C25B 1/23; C25B 1/55; C25B 11/093; C25B 11/02; C23C 16/40

(52) U.S. Cl. CPC C25B 11/052; C23C 16/45525; C25B 1/23; C23C 16/405; C25B 11/093; C25B 11/02; C23C 16/407; C25B 1/55

(57) ABSTRACT

An electrode of a chemical cell includes a structure having an outer surface, a plurality of catalyst particles distributed across the outer surface of the structure, and a catalyst layer disposed over the plurality of catalyst particles and the outer surface of the structure. Each catalyst particle of the plurality of catalyst particles includes a metal catalyst for reduction of carbon dioxide (CO₂) in the chemical cell. The catalyst layer includes an oxide material for the reduction of carbon dioxide (CO₂) in the chemical cell.

### CROSS-REFERENCE TO RELATED APPLICATION

This application claims the benefit of U.S. provisional application entitled “CO₂ Reduction into Syngas,” filed Jun. 17, 2019, and assigned Ser. No. 62/862,332, the entire disclosure of which is hereby expressly incorporated by reference.

### BACKGROUND OF THE DISCLOSURE

### Field of the Disclosure

The disclosure relates generally to photoelectrochemical and other chemical reduction of carbon dioxide (CO₂) into syngas, a mixture of carbon monoxide (CO) and hydrogen (H₂).

### Brief Description of Related Technology

Solar-powered CO₂ reduction with water (H₂O) has been proposed as a mechanism for reducing greenhouse gas (CO₂) emissions, while simultaneously converting renewable solar energy into storable, value-added fuels and other chemicals. The photoelectrochemical (PEC) route to CO₂ reduction combines light harvesting photovoltaic and electrochemical components into a monolithically integrated device.

Carbon monoxide (CO) is one of a wide variety of CO₂ reduction products. CO requires only two proton-electron transfers, and is thus a kinetically feasible choice compared to other products, such as CH₃OH and CH₄, which require six and eight proton-electron transfers to form one molecule, respectively.

CO is a useful bulk chemical. For instance, syngas, a mixture of CO and H₂, is a key feedstock for the production of methanol and other commodity hydrocarbons. The commodity hydrocarbons may be produced from syngas using well-established standard industrial processes, such as Fischer-Tropsch technology.

The above-referenced attributes of CO, together with the almost inevitable H₂ evolution in an aqueous PEC cell, can render syngas production from CO₂ and H₂O conversion a technologically and economically viable pathway to leverage established commercial processes for liquid fuels synthesis. Moreover, providing different CO/H₂ ratio in syngas mixtures can also be used for different downstream products (e.g., 1:3, 1:2 and 1:1 for methane, methanol and oxo-alcohols, respectively). Therefore, the syngas route provides a flexible platform for integration with a wide window of catalytic systems in a broad CO₂-recycling scheme without the strict requirement of suppression of the H₂ evolution reaction. However, it is challenging to achieve efficient and stable PEC CO₂ reduction into syngas with controlled composition owing to the difficulties associated with the chemical inertness of CO₂ and the complex reaction network of CO₂ conversion.

Various semiconductor photocathodes, including p-Si, ZnTe, CdTe, p-InP, Cu₂O and p-NiO, have been investigated for PEG CO₂ reduction into CO, usually in conjunction with a molecular metal-complex or metal co-catalyst (e.g., Au, Ag and derivatives) to realize selective CO production. However, it remains challenging to develop an efficient and stable PEC catalytic system capable of both activating inert CO₂ molecules at low overpotential or even spontaneously, as well as selectively producing syngas with controlled composition in a wide range to meet different downstream products. For instance, it has been reported that a pure metal catalyst with a simple mono-functional site usually has a weak interaction with the CO₂ molecule and cannot provide multiple sites for stabilizing the key reaction intermediates with optimal binding strength, which leads to impractically high overpotential and low catalytic efficiency and/or stability.

### SUMMARY OF THE DISCLOSURE

In accordance with one aspect of the disclosure, an electrode of a chemical cell includes a structure having an outer surface, a plurality of catalyst particles distributed across the outer surface of the structure, and a catalyst layer disposed over the plurality of catalyst particles and the outer surface of the structure. Each catalyst particle of the plurality of catalyst particles includes a metal catalyst for reduction of carbon dioxide (CO₂) in the chemical cell. The catalyst layer includes an oxide material for the reduction of carbon dioxide (CO₂) in the chemical cell.

In accordance with another aspect of the disclosure, a photocathode for a photoelectrochemical cell includes a substrate including a light absorbing material, the light absorbing material being configured to generate charge carriers upon solar illumination, an array of conductive projections supported by the substrate, each conductive projection of the array of conductive projections being configured to extract the charge carriers from the substrate, a plurality of catalyst particles distributed across each conductive projection of the array of conductive projections, and a catalyst layer disposed over the plurality of catalyst particles and each conductive projection of the array of conductive projections. Each catalyst particle of the plurality of catalyst particles includes a metal catalyst for reduction of carbon dioxide (CO₂) in the electrochemical cell. The catalyst layer includes an oxide material for the reduction of carbon dioxide (CO₂) in the electrochemical cell.

In accordance with yet another aspect of the disclosure, a method of fabricating an electrode of an electrochemical system includes depositing a plurality of catalyst particles across an outer surface of a structure of the electrode, each catalyst particle of the plurality of catalyst particles including a metal catalyst for reduction of carbon dioxide (CO₂) in the electrochemical system, and forming a catalyst layer over the plurality of catalyst particles and the outer surface of the structure, the catalyst layer including an oxide material for the reduction of carbon dioxide (CO₂) in the electrochemical system.

In connection with any one of the aforementioned aspects, the electrodes, systems, and/or methods described herein may alternatively or additionally include or involve any combination of one or more of the following aspects or features. The substrate includes a semiconductor material. The semiconductor material is configured to generate charge carriers upon absorption of solar radiation such that the chemical cell is configured as a photoelectrochemical system. The structure includes a substrate and an array of conductive projections supported by the substrate. The array of conductive projections defines the outer surface of the structure. The array of conductive projections are configured to extract the charge carriers generated in the substrate. Each conductive projection of the array of conductive projections includes a respective nanowire. Each conductive projection of the array of conductive projections includes a Group III-V semiconductor material. The structure is planar. The metal catalyst is platinum or palladium. The oxide material includes titanium dioxide (TiO₂) or zinc oxide (ZnO). Each catalyst particle of the plurality of catalyst particles is configured as a nanoparticle. Each catalyst particle of the plurality of catalyst particles has a diameter falling in a range from about 2 nanometers to about 3 nanometers. The catalyst layer has a thickness falling in a range from about 0.3 nanometers to about 3 nanometers. The chemical cell is a thermochemical cell. An electrochemical system includes a working electrode configured in accordance with the electrode as described herein, and further includes a counter electrode, an electrolyte in which the working and counter electrodes are immersed, and a voltage source that applies a bias voltage between the working and counter electrodes. The bias voltage establishes a ratio of CO₂ reduction to hydrogen (H₂) evolution at the working electrode. A photoelectrochemical system includes a working photocathode configured in accordance with the photocathode described herein, and further includes a counter electrode, an electrolyte in which the working photocathode and the counter electrode are immersed, and a voltage source that applies a bias voltage between the working photocathode and the counter electrode. The bias voltage establishes a ratio of CO₂ reduction to hydrogen (H₂) evolution at the working electrode. Depositing the plurality of catalyst particles includes implementing a photodeposition process, the photodeposition process being configured to deposit nanoparticles of the metal catalyst. Forming the catalyst layer includes implementing an atomic layer deposition (ALD) process, the ALD process being configured to deposit a nanolayer of the oxide material. The method further includes growing an array of nanowires on a semiconductor substrate to form the structure of the electrode and define the outer surface.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 is a schematic view and block diagram of an electrochemical system having a working electrode with metal/oxide co-catalysts in accordance with one example.

FIG. 2A is a schematic, partial view of a photocathode having a nanowire array with metal/oxide co-catalysts in accordance with one example.

FIGS. 2B and 2C are scanning electron microscopy (SEM) and transmission electron microscopy (TEM) images of a photocathode and nanowire, respectively, with metal/oxide co-catalysts configured in accordance with one example.

FIG. 3 is a high resolution TEM (HRTEM) image of a nanowire having metal/oxide co-catalysts in accordance with one example, the image having been taken from above the nanowire, together with plots of energy-dispersive X-ray spectroscopy (EDX) analysis of the nanowire at interior and edge positions.

FIG. 4 is a method of fabricating an electrode with metal/oxide co-catalysts in accordance with one example.

FIG. 5 depicts plots of performance parameters of an electrode having metal/oxide co-catalysts in accordance with one example, including Faradaic efficiencies (FEs), chronoamperometry data, current density curves.

FIG. 6 depicts side views of optimized configurations of CO₂ adsorbed on different electrode surfaces, as well as a plot of differential charge density with calculated free energy diagrams.

FIG. 7 depicts X-ray photoelectron spectroscopy (XPS) and electron localized function (ELF) plots for platinum-based catalyst surfaces.

FIG. 8 depicts plots of Faradaic efficiency for CO, and calculated free energy diagrams for CO₂ reduction to CO, of electrodes having metal/oxide co-catalysts in accordance with two examples.

FIG. 9 is a plot comparing the CO Faradaic efficiency of an electrode in accordance with one example with several other electrodes.

FIG. 10 is a plot of current density curves of an electrode having co-catalysts in accordance with one example.

FIG. 11 is a plot of chronoamperometry data of an electrode having co-catalysts in accordance with one example at various applied potentials.

FIG. 12 is a plot of partial current density for CO and H2 for an electrode having co-catalysts in accordance with one example.

FIG. 13 is a Tafel plot for CO and H2 evolution for an electrode having co-catalysts in accordance with one example.

FIG. 14 is a plot of current density curves for electrodes having co-catalysts in accordance with several examples having different oxide thicknesses.

FIG. 15 is a plot of Faradaic efficiencies of electrodes having co-catalysts in accordance with several examples having different oxide thicknesses.

The embodiments of the disclosed electrodes, devices, systems, and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Electrodes of photoelectrochemical and other chemical cells having a metal/oxide interface for reduction of carbon dioxide (CO₂) into syngas are described. Methods of fabricating photocathodes and other electrodes for use in photoelectrochemical and other chemical systems are also described. The metal/oxide interface includes metal catalyst particles and an oxide catalyst layer covering the catalyst particles. The metal catalyst particles and the oxide catalyst layer together provide a co-catalyst interface for CO₂ reduction. The metal/oxide interface spontaneously activates the CO₂ molecules and stabilizes the key reaction intermediates to facilitate CO production. Both efficiency and stability are improved. For instance, solar-to-syngas efficiency of 0.87% and a high turnover number of 24800 are attained in combination with a desirable high stability of 10 hours. Moreover, the ratio of CO/H₂ produced via the disclosed electrodes may be tuned in a wide range, e.g., between 4:1 and 1:6 with a total unity Faradaic efficiency.

The metal/oxide interface of the disclosed electrodes provides multifunctional catalytic sites with complementary chemical properties for CO₂ activation and conversion. This aspect of the catalytic sites leads to a unique pathway inaccessible with, or otherwise not provided by, the individual catalyst components alone. The metal/oxide interface provides the multifunctional combination of metal and oxide catalytic sites with complementary chemical properties, which opens new reaction channels that are not possible with the individual catalyst components alone. The metal/oxide interfaces of the disclosed electrodes thereby present useful improvements to high-performance PEC systems for selective CO₂ reduction into valuable carbon-based chemicals and fuels.

The metal/oxide interface is not limited to a particular metal catalyst or a particular oxide material. The versatility of the metal/oxide interface of the disclosed electrodes is demonstrated by the combination of different metals (e.g., Pt and Pd) and oxides (TiO₂ and ZnO). Although pristine metal catalytically favors the proton reduction to evolve H₂, the coverage of metal with the metal-oxide layer to form the metal/oxide interface exhibits preferential activity for CO₂ reduction over H₂ evolution. As an example, by rationally integrating a Pt/TiO₂ co-catalyst with the strong light harvesting of a p-n Si junction and the efficient electron extraction effect of GaN nanowire arrays (Pt—TiO₂/GaN/n⁺-p Si), the above-referenced half-cell solar-to-syngas (STS) efficiency and benchmark turnover number (TON) levels were achieved in an aqueous PEC system.

Although described herein in connection with electrodes having GaN-based nanowire arrays for PEC CO₂ reduction, the disclosed electrodes are not limited to PEC reduction or nanowire-based electrodes. A wide variety of types of chemical cells may benefit from use of the metal/oxide interface, including, for instance, electrochemical cells and thermochemical cells. The nature, construction, configuration, characteristics, shape, and other aspects of the structures to which the metal/oxide interface is deposited may thus vary.

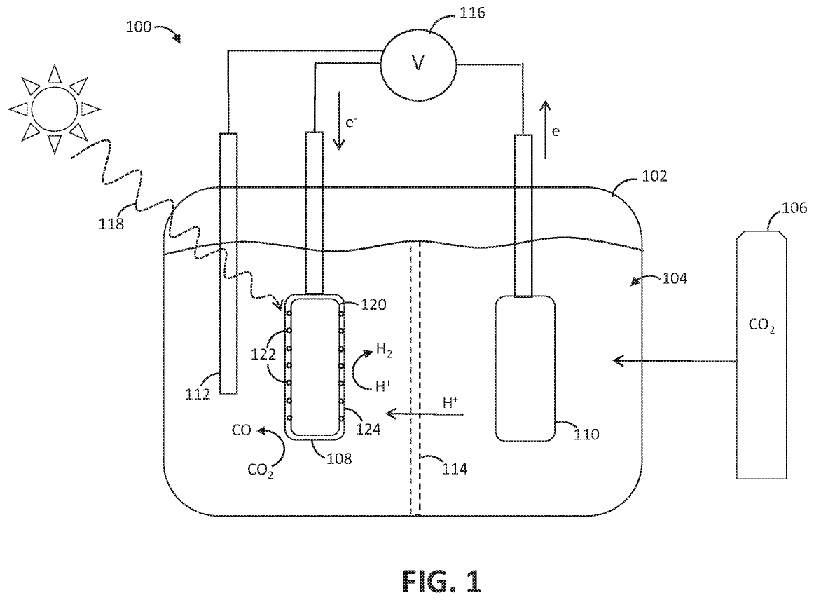

FIG. 1 depicts a system 100 for reduction of CO₂ into CO and H₂O. The system 100 may also be configured for evolution of H₂. The system 100 may thus produce syngas at a desired ratio of CO and H₂. The system 100 may be configured as an electrochemical system. In this example, the electrochemical system 100 is a photoelectrochemical (PEC) system in which solar or other radiation is used to facilitate the CO₂ reduction. The manner in which the PEC system 100 is illuminated may vary. In thermochemical examples, the source of radiation may be replaced by a heat source.

The electrochemical system 100 includes one or more electrochemical cells 102. A single electrochemical cell 102 is shown for ease in illustration and description. The electrochemical cell 102 and other components of the electrochemical system 100 are depicted schematically in FIG. 1 also for ease in illustration. The cell 102 contains an electrolyte solution 104 to which a source 106 of CO₂ is applied. In some cases, the electrolyte solution is saturated with CO₂. Potassium bicarbonate KHCO₃ may be used as an electrolyte. Additional or alternative electrolytes may be used. Further details regarding one example of the electrochemical system 100 are provided below.

The electrochemical cell 102 includes a working electrode 108, a counter electrode 110, and a reference electrode 112, each of which is immersed in the electrolyte 104. The counter electrode 110 may be or include a metal wire, such as a platinum wire. The reference electrode 112 may be configured as a reversible hydrogen electrode (RHE). The configuration of the counter and reference electrodes 110, 112 may vary. For example, the counter electrode 110 may be configured as, or otherwise include, a photoanode at which water oxidation (2H₂O⇔O2+4e⁻+4H⁺) occurs.

Both reduction of CO₂ to CO and evolution of H₂ occur at the working electrode 112 as follows:
CO₂ reduction: CO₂+2H++2e⁻⇔CO+H₂O
H₂ evolution: 2H⁺+2e⁻⇔H₂
   To that end, electrons flow from the counter electrode 110 through a circuit path external to the electrochemical cell 102 to reach the working electrode 108. The working and counter electrodes 108, 110 may thus be considered a cathode and an anode, respectively.

In the example of FIG. 1, the working and counter electrodes are separated from one another by a membrane 114, e.g., a proton-exchange membrane. The construction, composition, configuration and other characteristics of the membrane 114 may vary.

In this example, the circuit path includes a voltage source 116 of the electrochemical system 100. The voltage source 116 is configured to apply a bias voltage between the working and counter electrodes 108, 110. The bias voltage may be used to establish a ratio of CO₂ reduction to hydrogen (H₂) evolution at the working electrode, as described further below. The circuit path may include additional or alternative components. For example, the circuit path may include a potentiometer in some cases.

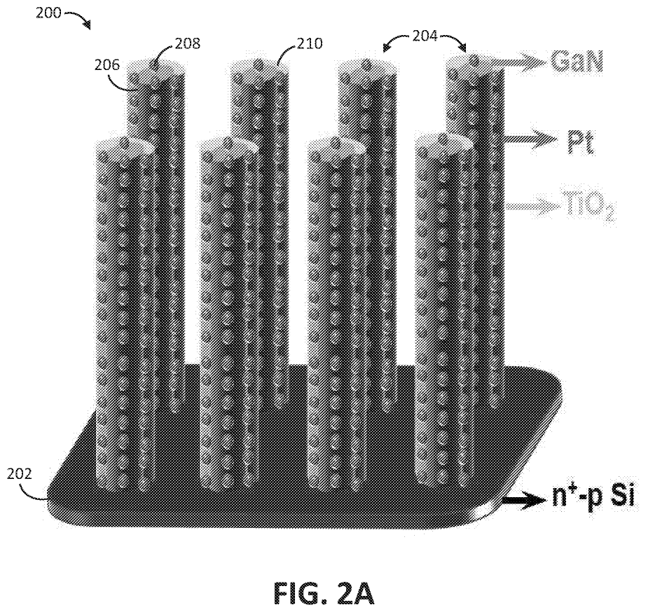

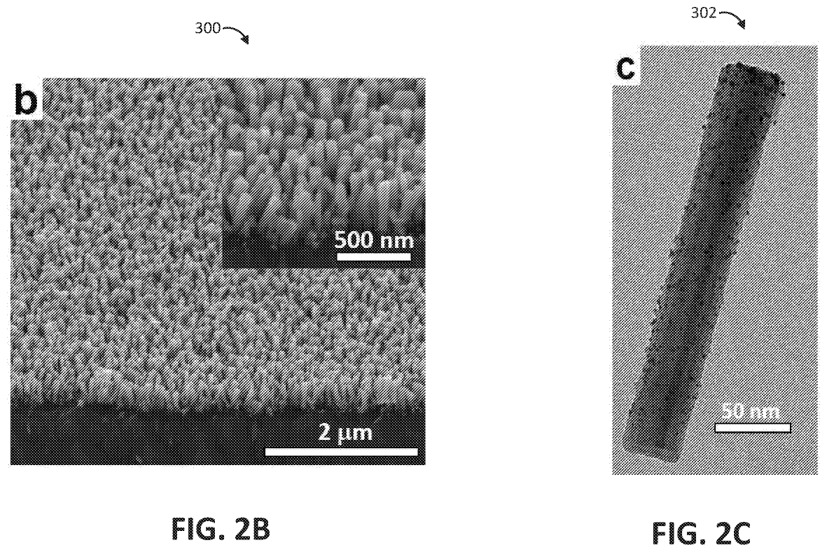

In some cases, the working electrode 108 is configured as a photocathode. Light 118, such as solar radiation, may be incident upon the working electrode 108 as shown. The electrochemical cell 102 may thus be considered and configured as a photoelectrochemical cell. In such cases, illumination of the working electrode 108 may cause charge carriers to be generated in the working electrode 108. Electrons that reach the surface of the working electrode 108 may then be used in the CO₂ reduction and/or the H₂ evolution. The photogenerated electrons augment the electrons provided via the current path. The photogenerated holes may move to the counter electrode for the water oxidation. Further details regarding examples of photocathodes are provided below in connection with, for instance, FIGS. 2A-2D.

The working electrode 108 includes a platform, framework, or other structure 120. The structure 120 of the working electrode 108 may constitute the interior of the working electrode 108. The structure 120 may be a uniform or composite structure. For example, the structure 120 may include a semiconductor wafer or other substrate with any number of layers and/or patterned structures disposed thereon. For example, the structure 120 may include a substrate and an array of nanowires disposed thereon, as described below. The structure 120 may or may not be monolithic. The shape of the structure 120 may also vary. For instance, the structure 120 may or may not be planar. In non-planar cases, the structure 120 may have a nanostructured surface, as described in connection with a number of examples below. In other cases, the exterior surface of the working electrode 108 may be flat.

The structure 120 of the working electrode 108 may be active (functional) or passive (structural). For example, the structure 120 may be configured and act solely as a support structure for the catalyst arrangement formed along an exterior surface of the working electrode 108. Alternatively, some or all of the structure 120 may be configured for photogeneration of electron-hole pairs.

The structure 120 of the working electrode 108 establishes an outer surface at which a co-catalyst arrangement is provided. The co-catalyst arrangement includes a plurality of catalyst particles 122 and a catalyst layer 124. The catalyst particles 122 are distributed across the outer surface of the structure 120. The catalyst layer 124 is disposed over the catalyst particles 122 and the outer surface of the structure 120 (e.g., those portions of the outer surface not covered by the catalyst particles 122).

The distribution of the catalyst particles 122 may be uniform or non-uniform. The catalyst particles 122 may thus be distributed randomly across the outer surface of the structure 120. The symmetrical arrangement shown in FIG. 1 is for ease in illustration.

Each catalyst particle 122 is composed of, or otherwise includes, a metal catalyst for reduction of carbon dioxide (CO₂) in the electrochemical cell 102. For example, each catalyst particle 122 may be a particle of elemental or purified metal. Alternatively, a metal alloy or other metal-based material may be used. In some cases, the metal catalyst is or includes platinum (Pt). Other metals may be used. For example, palladium (Pb) may be used as or in the metal catalyst.

The catalyst particles 122 are not shown to scale in FIG. 1. In some cases, each catalyst particle 122 is configured as a nanoparticle. For instance, each catalyst particle 122 may have a diameter falling in a range from about 2 nanometers to about 3 nanometers, although other particle sizes may be used. Further details regarding example nanoparticles and sizes are provided below.

The catalyst layer 124 is composed of, or otherwise includes, an oxide material for the reduction of carbon dioxide (CO₂) in the electrochemical cell 102. In some cases, the oxide material is or includes a metal-oxide material. For example, the oxide material may be or include titanium dioxide (TiO₂). Other oxide materials may be used, including, for instance, zinc oxide (ZnO).

The catalyst layer 124 is also not shown to scale in FIG. 1. In some cases, the catalyst layer 124 is configured as a nanolayer. For example, the catalyst layer 124 may have a thickness falling in a range from about 0.3 nanometers to about 3 nanometers, but other thicknesses may be used. Further details regarding example nanolayers and thicknesses are provided below.

FIG. 2A depicts a photocathode 200 in accordance with one example. The photocathode 200 may be used as the working electrode 108 in the system 100 of FIG. 1, and/or another photoelectrochemical cell or system. The photocathode 200 is shown schematically, and with partial transparency of layers, for ease in illustration of the elements thereof.

The photocathode 200 includes a substrate 202. The substrate 202 may include a light absorbing material. The light absorbing material is configured to generate charge carriers upon solar or other illumination. The light absorbing material has a bandgap such that incident light generates electron-hole pairs within the substrate 202. In some cases, the substrate 202 is composed of, or otherwise includes, silicon. For instance, the substrate 202 may be provided as a silicon wafer. The silicon may be doped. In the example of FIG. 2A, the substrate 202 is heavily n-type doped, and moderately or lightly p-type doped. The doping arrangement may vary. For example, one or more components of the substrate 202 may be non-doped (intrinsic), or effectively non-doped. The substrate 202 may include alternative or additional layers, including, for instance, support or other structural layers. In other cases, the substrate 202 is not light absorbing. In these and other cases, one or more other components of the photocathode 200 may be configured to act as a light absorber.

The photocathode 200 includes an array of conductive projections 204 supported by the substrate 202. Each conductive projection 204 is configured to extract the charge carriers (e.g., electrons) from the substrate 202. The extraction brings the electrons to external sites along the conductive projections 204 for use in the CO₂ reduction and H₂ evolution. In some cases, each conductive projection 204 is configured as a nanowire. Each conductive projection 204 may include a semiconductor core 206. In some cases, the core is or otherwise includes Gallium nitride (GaN). Other semiconductor materials may be used, including, for instance, other Group III-V nitride semiconductor materials. The core 206 of each nanowire or other conductive projection may be or include a columnar, post-shaped, or other elongated structure that extends outward (e.g., upward) from the plane of the substrate 202. The semiconductor nanowires may be grown or formed as described in U.S. Pat. No. 8,563,395, the entire disclosure of which is hereby incorporated by reference. The conductive projections 204 may be referred to herein as nanowires with the understanding that the dimensions, size, shape, composition, and other characteristics of the projections 204 may vary.

In some cases, one or more of the nanowires 204 is configured to generate electron-hole pairs upon illumination. For instance, the nanowires 204 may be configured to absorb light at frequencies different than other light absorbing components of the photocathode 200. For example, one light absorbing component, such as the substrate 202, may be configured for absorption in the visible or infrared wavelength ranges, while another component may be configured to absorb light at ultraviolet wavelengths. In other cases, the nanowires 204 are the only light absorbing component of the photocathode 200.

The photocathode 200 of FIG. 2A presents another example of the co-catalyst arrangement described herein. Each nanowire 204 has a plurality of catalyst particles 208, e.g., nanoparticles, distributed across the respective surface(s) of the semiconductor core 206. In the example of FIG. 2A, the catalyst particles 208 are disposed along sidewalls of the semiconductor core 206. The distribution may not be uniform or symmetric as shown. As described herein, each catalyst particle 208 may include or be composed of a metal catalyst, such Pt or Pb, for reduction of carbon dioxide (CO₂) in a photoelectrochemical cell.

Each nanowire 204 also has a catalyst layer 210, e.g., a nanolayer, disposed over the plurality of catalyst particles 208. As shown in FIG. 2A, the catalyst layer 210 may cover each particle 208, as well as portions of the semiconductor core 206 not covered by one of the particles 208. In some cases, the catalyst layer 210 may cover other portions of the photocathode 200, such as the substrate 202. The catalyst layer 210 is composed of, or includes, an oxide material for the reduction of carbon dioxide (CO₂) in the photoelectrochemical cell. The oxide material may be or include titanium dioxide (TiO₂), zinc oxide (ZnO), and/or another metal-oxide material, but other oxide materials may be alternatively or additionally used.

Further details are now provided in connection with examples co-catalyst arrangements in which platinum (Pt) nanoparticles and a titanium dioxide (TiO₂) nanolayer are used. A GaN nanowire array supported by a silicon substrate provided a platform and heterostructure for the co-catalyst arrangement, as described above. Such a structure takes advantage of the strong light absorption capability of Si (bandgap of 1.1 eV) and efficient electron extraction effect as well as large surface area provided by the GaN nanowires. Moreover, the light absorption and catalytic reaction sites are decoupled spatially in the structure, providing a useful platform to support the co-catalysts and improve the catalytic performance without affecting optical properties. As described herein, the intimate Pt/TiO₂ interface provides multiple sites and unique channels that facilitate the CO₂ activation and reaction pathways for syngas production.

The morphology and chemical composition of the Pt—TiO₂/GaN/n⁺-p Si heterostructures were studied using scanning electron microscopy (SEM), transmission electron microscopy (TEM), energy-dispersive X-ray spectroscopy (EDX) and inductively coupled plasma-atomic emission spectroscopy (ICP-AES) analysis.

FIGS. 2B and 2C depict the heterostructure of the nanowires and co-catalyst interface. FIG. 2B is a cross-sectional (45°-tilted) SEM image 300 that shows GaN nanowire growth vertically on the Si substrate. The cross-sectional SEM image 300 shows that the GaN nanowires are aligned vertically to the Si substrate with an average diameter of ˜50 nm (±15 nm) and height of 250 nm (±50 nm). FIG. 20 is a TEM image 302 that illustrates Pt nanoparticles distributed uniformly on the GaN nanowire surface. The TEM image 302 reveals that the Pt nanoparticles are of 2-3 nm size and uniformly deposited on the GaN nanowire surface.

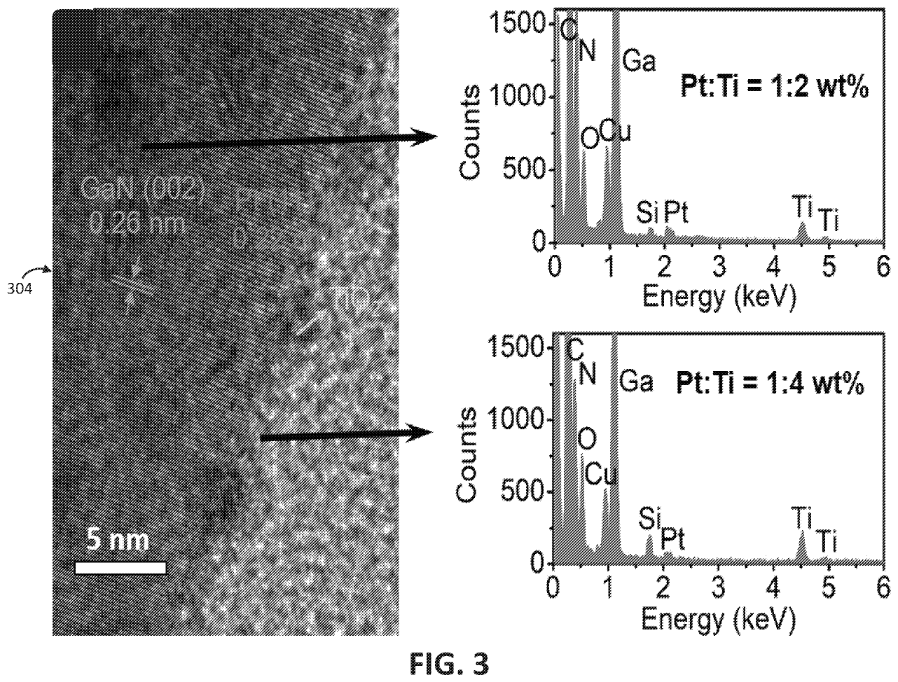

FIG. 3 shows a high-resolution TEM (HRTEM) image 304, along with EDX plots of the composition in the center and edge regions of the nanowire. The EDX analysis confirms the coating of the GaN nanowire with ultrathin TiO₂ layer. The TiO₂ layer is amorphous and has a thickness of ˜1 nm, which corresponds to 18 ALD cycles of TiO₂ deposition. The TEM image 304 depicts lattice spacings of 0.22 nm and 0.26 nm, which correspond to the (111) facet of Pt and (002) lattice plane of GaN, respectively, indicating the preferred nanowire growth along [symbol] 0001 [symbol] direction (c-axis). The loading amounts of Pt and Ti in Pt—TiO₂/GaN/n⁺-p Si were determined to be 4.9 and 48.3 nmol cm⁻², respectively, by using ICP-AES analysis. The copper (Cu) peaks in the EDX plots amount to measurement artifacts arising from the TEM sample grid.

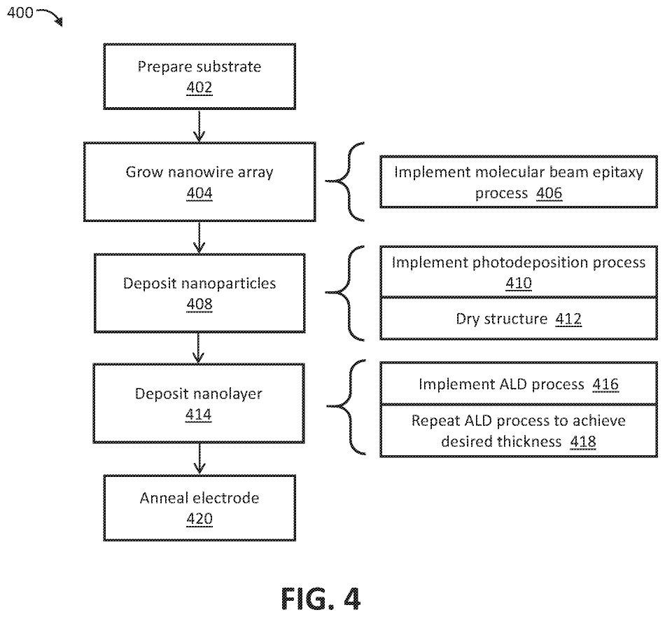

FIG. 4 depicts a method 400 of fabricating an electrode of an electrochemical system in accordance with one example. The method 400 may be used to manufacture any of the working electrodes described herein or another electrode. The method 400 may include additional, fewer, or alternative acts. For instance, the method 400 may or may not include one or more acts directed to growing a nanowire array (act 404).

The method 400 may begin with an act 402 in which a substrate is prepared. The substrate may be or be formed from a p-n Si wafer. In one example, a 2-inch Si wafer was used, but other (e.g., larger) size wafers may be used. Other semiconductors and substrates may be used. Preparation of the substrate may include one or more thermal diffusion procedures.

In the example of FIG. 4, the method 400 includes an act 404 in which GaN or other nanowire arrays are grown or otherwise formed on the substrate. The nanowire growth may be achieved in an act 406 in which plasma-assisted molecular beam epitaxy is implemented. The act 406 may be implemented under nitrogen-rich conditions. In one example, the growth conditions were as follows: a growth temperature of 790° C. for 1.5 hours, a Ga beam equivalent pressure of about 6×10⁻⁸ Torr, a nitrogen flow rate of 1 standard cubic centimeter per minute (sccm), and a plasma power of 350 W. The nanowires provide platforms or other structures for the co-catalysts deposited in the following steps. Other platforms or structures may be formed.

In an act 408, a plurality of catalyst particles are deposited across one or more outer surfaces of the nanowires or other structures of the electrode. The particles may be nanoparticles. Each nanoparticle may be composed of a metal, as described herein. The act 408 may include implementation of a photodeposition process in an act 410, after which the structure is dried in an act 412. Alternative or additional deposition procedures may be used. Further details regarding examples of the particle deposition are provided below.

In one example, Pt nanoparticles were photodeposited on an GaN/n⁺-p Si wafer sample in a sealed Pyrex chamber with a quartz lid. A solution of 60 mL deionized water (purged with Ar for 20 min prior to the usage), 15 mL methanol, and 20 μL of 0.2 M H₂PtCl₆ (99.9%, Sigma Aldrich) was added in the chamber. The chamber was then evacuated and irradiated for 30 min using 300 W Xe lamp (Excelitas Technologies) for the photodeposition of Pt nanoparticles. Then the Pt deposited sample was taken out and dried for TiO₂ deposition. The deposition procedure for Pd-based nanoparticles may be similar, except for use of Pd(NO₃)₂ (99%, Sigma Aldrich) instead of H₂PtCl₆ in the photodeposition process.

The method 400 then includes an act 414 in which a catalyst layer is formed over the plurality of catalyst particles and the outer surface of the structure. The catalyst layer may be or include one or more nanolayers. The nanolayer may be composed of an oxide material, as described herein. The nanolayer(s) may be deposited using an atomic-layer deposition (ALD) process implemented in an act 416. The ALD process may be repeated (act 418) a number of times (e.g., 18) to achieve a desired thickness of the nanolayer. Further details regarding examples of the nanolayer deposition are provided below.

In one example, a TiO₂ ultrathin film was deposited with a Gemstar Arradiance 8 ALD tool using Tetrakis(dimethylamido)-titanium (TDMAT, Sigma-Aldrich) and deionized water as reactants at 225° C. In an ALD cycle, TDMAT was pulsed into the chamber for 0.7 s with a N₂ purge time of 23 seconds, after which water was pulsed into the chamber for 0.022 seconds before another 23-second purge with N₂. The ALD cycling was repeated 18 times, which provided a TiO₂ film of 1 nm thickness.

The act 414 may differ for other types of catalyst layers. For instance, a ZnO ultrathin film may be photodeposited using 10 μL of 0.2 M Zn(NO₃)₂ (98%, Sigma Aldrich) as the precursor in 75 ml aqueous methanol (20 vol %) solution for 30 minutes under 300 W Xe lamp irradiation.

In some cases, the method 400 includes an act 420 in which the electrode is annealed. One example electrode was annealed at 400° C. for 10 minutes in forming gas (5% H₂, balance N₂) at a flow rate of 200 sccm. The parameters of the anneal process may vary.

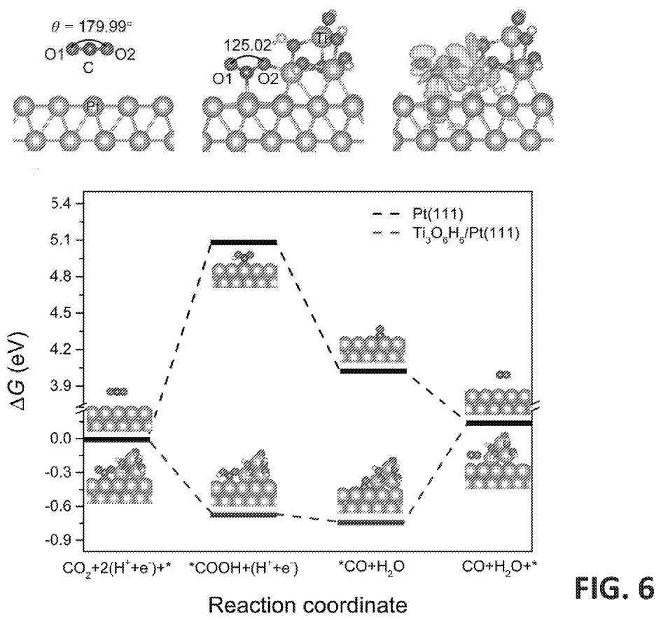

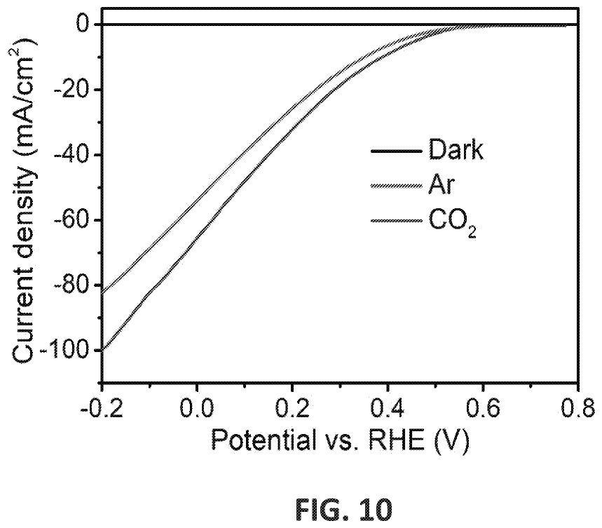

Details regarding photoelectrochemical (PEC) performance of the co-catalyst arrangement of the disclosed PEG electrodes are now provided in connection with FIGS. 6-15. PEG performance was investigated in CO₂-saturated 0.5 M KHCO₃ solution (pH 7.5) under 300 W xenon lamp irradiation (800 mW cm⁻²) in a conventional three-electrode cell. To reveal the interaction of photocathode with CO₂, the current-potential (J-V) curves of Pt—TiO₂/GaN/n⁺-p Si in a CO₂ or Ar-saturated electrolyte was compared (see FIG. 10). There is a large enhancement in the photocurrent generation under CO₂ atmosphere compared to that of Ar atmosphere, indicating an interaction between the electrode surface and CO₂ molecule for CO₂ reduction.

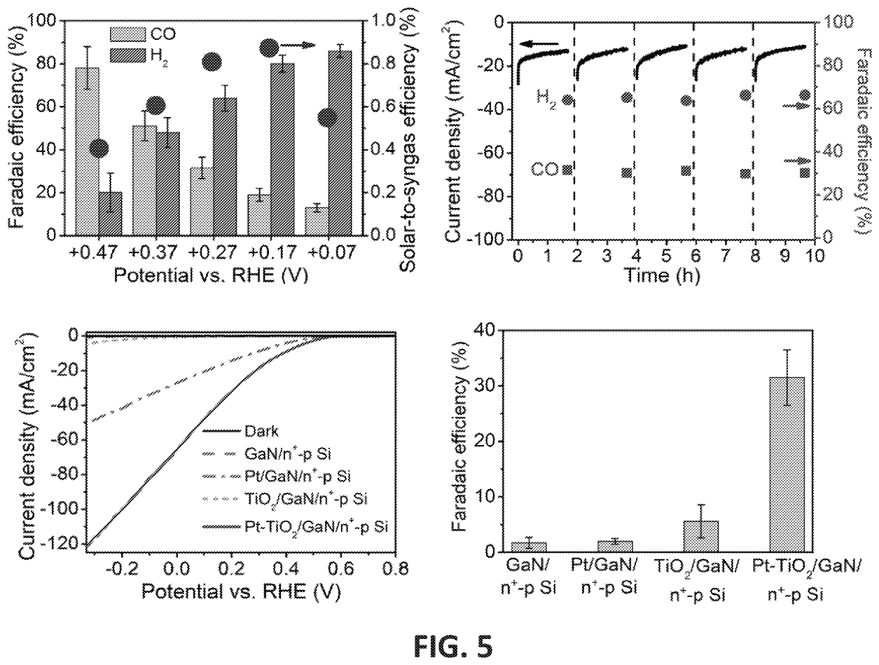

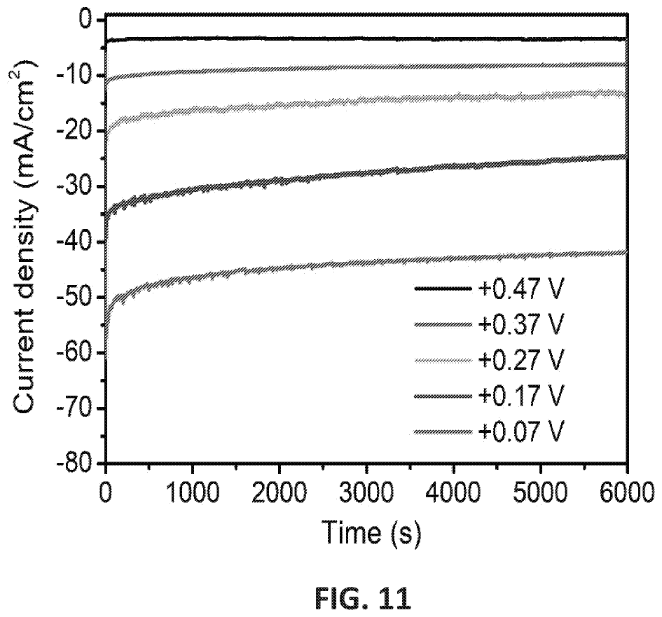

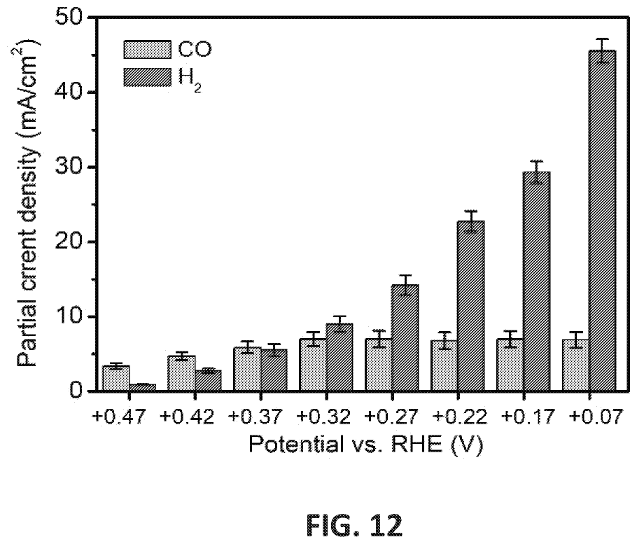

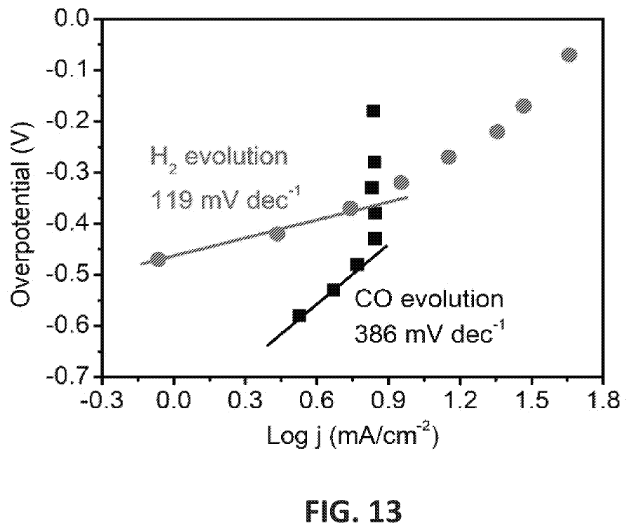

FIG. 5 shows the Faradaic efficiencies (FEs) for CO and H₂on Pt—TiO₂/GaN/n⁺-p Si at applied potential between +0.47 V and +0.07 V vs. reversible hydrogen electrode (RHE) in CO₂-saturated electrolyte. Hereafter, all the potentials are referenced to the RHE unless otherwise specified. The corresponding chronoamperometry data at different applied potentials are shown in FIG. 11. At an applied potential of +0.47 V, the photocathode exhibited a high CO FE of 78%, indicating the major extracted photogenerated electrons were used for selectively CO₂-to-CO conversion at the catalyst surface. By tuning the potential from +0.47 V to +0.07 V, the CO/H₂ ratio can be tuned in a large range between 4:1 and 1:6. At +0.27 V, a CO/H₂ ratio of 1:2 is obtained, which is a desirable composition of syngas mixtures for methanol synthesis and Fischer-Tropsch hydrocarbon formation. The decreased CO FE at a more negative potential than +0.37 V is mainly due to the limited CO₂ mass transport in the electrolyte at high CO generation rate. The kinetic limitation was evidenced by the saturated current density for CO generation in the high applied bias region (FIG. 12). In addition, different Tafel slopes for the CO₂ reduction and H₂ evolution reactions could lead to the above-mentioned bias-dependent reaction selectivity. To evaluate their contribution, the Tafel plots for CO and H₂ evolution were drawn by using the corresponding partial current density, as shown in FIG. 13. The Tafel slopes were calculated by using data points more positive than +0.37 V vs. RHE, as the slope increases dramatically at more negative potentials due to the mass-transport limitations. It was found that the Tafel slopes for CO and H₂ evolution were 386 and 119 mV dec⁻¹, respectively. The different Tafel slopes result in the bias-dependent reaction selectivity largely in the low bias region. At all the applied potentials, a total FE of 97±8% was obtained for the co-generation of CO and H₂, with no appreciable amount of other gas products detected by gas chromatograph (GC) and liquid products (e.g. HCOOH and CH₃OH) analyzed by nuclear magnetic resonance (NMR) spectroscopy. To demonstrate that the generated CO from CO₂ reduction, isotopic experiment using ¹³CO₂ was conducted. The signal at m/z=29 assigned to ¹³CO appeared in the gas chromatography-mass spectrometry analysis, indicating the CO product is formed from the reduction of CO₂.

FIG. 5 also depicts chronoamperometry data and FEs for CO and H₂ of Pt—TiO₂/GaN/n⁺-p Si photocathode at +0.27 V relative to a reversible hydrogen electrode (RHE) reference, with the dashed lines denoting cleaning of the photoelectrode and purging of the PEC cell with CO₂, current density (J-V) curves of bare GaN/n⁺-p Si, GaN/n⁺-p Si with individual Pt or TiO₂ co-catalyst, and Pt—TiO₂/GaN/n⁺-p Si, and Faradaic efficiencies for CO at +0.27 V relative to the RHE reference, with the FEs for CO of GaN/n⁺-p Si and TiO₂/GaN/n⁺-p Si photocathodes measured at −0.33 V vs. the RHE reference due to the negligible photocurrent at an applied positive potential.

One useful aspect of the disclosed electrodes is the highly positive onset potential of +0.47 V (underpotential of 580 mV to the CO₂/CO equilibrium potential at −0.11 V) for producing high CO FE of 78% in an aqueous PEC cell. Among various reported photocathodes, the above-referenced example photocathode featured the lowest onset potential, which is 170 mV positive shifted compared with the best value reported in the literature. The extremely low onset potential of the photocathode is attributed to coupling effects including strong light harvesting of p-n Si junction, efficient electron extraction of GaN nanowire arrays, and extremely fast syngas production kinetics on Pt—TiO₂ dual co-catalysts. The STS efficiencies of the PEC system at different applied potentials are calculated according to the measured photocurrent density and FEs for CO and H₂ (see Equation 1 below). As shown in FIG. 5, at +0.17 V, the STS efficiency reached 0.87%, which greatly outperforms other reported photocathodes.

The durability of the Pt—TiO₂/GaN/n⁺-p Si photocathode was investigated at a constant potential of +0.27 V by five consecutive runs with each run of 2 hours (h), as shown in FIG. 5. After each cycle, the products of CO and H₂ were analyzed by GC, the electrode was thoroughly cleaned by deionized water and the PEC cell was purged by CO₂ for 20 minutes (min). During the five runs of 10 h operation, the electrode showed similar behavior in terms of photocurrent density and product selectivity, indicating the high stability of the sample during the syngas production process. The initial decrease of high photocurrent density in each run is likely due to the limited mass transfer of reactants or products at high reaction rates, which can be recovered in the next run after the cleaning of photoelectrode surface. The CO/H₂ ratio in the products was kept nearly 1:2 during the five cycles of operation, which is a desirable syngas composition for synthetizing downstream products including methanol and liquid hydrocarbons. In addition, the SEM, TEM, and XPS analysis of Pt—TiO₂/GaN/n⁺-p Si photocathode after the PEG reaction were performed. No appreciable change of GaN nanowires and Pt—TiO₂ catalysts were found. The total turnover number (TON), defined as the ratio of the total amount of syngas evolved (264 nmol) to the amount of Pt—TiO₂ catalyst (10.64 nmol, calculated from the catalyst loadings and electrode sample area of 0.2 cm²), reached 24800, which is at least 1 or 2 orders of magnitude higher than previously reported values for syngas or CO formation from PEC or photochemical CO₂ reduction.

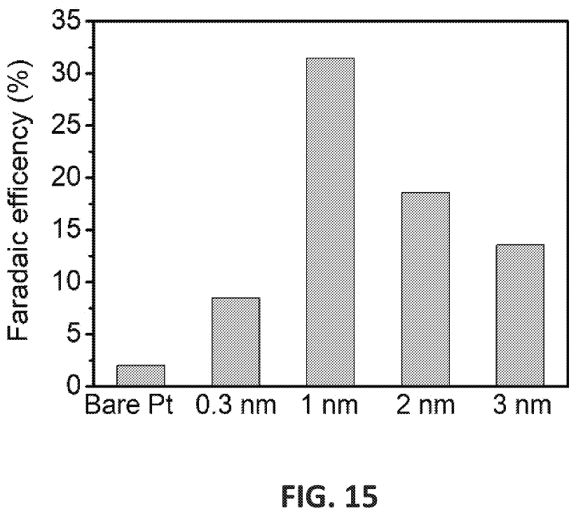

To understand the underlying catalytic mechanism and the role of basic components for the PEG performance of the Pt—TiO₂/GaN/n⁺-p Si photocathode, a series of control experiments were conducted. FIG. 5 shows the comparison of current density (LSV) curves for bare GaN/n⁺-p Si, GaN/n⁺-p Si with individual Pt or TiO₂ co-catalyst, and Pt—TiO₂/GaN/n⁺-p Si. The bare GaN/n⁺-p Si displays a poor PEC performance with a negligible photocurrent density and highly negative onset potential. The loading of Pt co-catalyst can greatly improve the PEC performance with an onset potential of about +0.47 V and photocurrent density of ˜50 mA cm⁻² at −0.33 V, while TiO₂ alone shows a small photocurrent density of 5 mA cm⁻² at −0.33 V. Compared to bare Pt, significantly higher photocurrent density of ˜120 mA cm⁻² at −0.33 V is attained when Pt and TiO₂ are loaded simultaneously. It is proposed that the formation of intimate Pt/TiO₂ interface stabilizes the reaction intermediates and reduces the activation barrier for syngas production, which are validated by theoretical calculations discussed below. In addition, the ultrathin TiO₂ overlayer may passivate the nanowire surface states and reduce the probability of electron-hole recombination at the surface. It is also proposed that the Pt/TiO₂ interface is more resistant to CO poisoning than Pt alone as shown in thermochemical catalysis, which could contribute to the enhanced syngas production on metal/oxide interface. FIG. 5 also shows the comparison of FEs of CO for the four samples. Besides CO product, the remaining balance of photocurrent drives H₂ evolution from proton reduction. It is shown that CO FEs are very low on bare GaN/n⁺-p Si, and with individual Pt or TiO₂ co-catalyst (1.7%, 2% and 5.6%, respectively). In contrast, the CO formation selectivity increases greatly to 32% by loading Pt—TiO₂ dual co-catalyst, indicating a synergetic effect between Pt and TiO₂. The synergy is attributed to the strong interaction at the intimate metal/oxide interface, which provides the multifunctional adsorption/reaction sites for CO₂ activation and conversion. There is an optimized thickness of ˜1 nm TiO₂ for maximum catalytic activity and CO selectivity (see, e.g., FIG. 15). Very thin TiO₂ deposition yields less interfacial reactive sites, while increasing the TiO₂ thickness over 1 nm resulted in limited mass transport of reactants to the interfacial sites and large tunneling resistance to charge carrier transport associated with thick TiO₂ layer.

FIG. 6 is directed to analyzing the role of the metal/oxide interface in connection with CO₂ adsorption and activation. To elucidate the role of metal/oxide interface for the conversion of CO₂ to CO from the fundamental atomic level, density functional theory (DFT) calculations were employed using Ti₃O₆H₆/Pt(111) to describe the Pt/TiO₂ interface. The hydroxylation of Titania cluster (Ti₃O₆H₆) was considered in the calculations to account for the effect of PEC CO₂ reduction conditions in an aqueous environment. As CO₂ adsorption and activation on catalyst surface is the initial and often the rate-determining step for the whole CO₂ reduction process, the CO₂ adsorption characteristics on Ti₃O₆H₆/Pt(111) surface is investigated. The calculation of CO₂ adsorption on pristine Pt(111) was also performed as a comparison. FIG. 6 shows the optimized configurations of CO₂ adsorption on the pristine Pt(111) and Ti₃O₆H₆/Pt(111) surface, respectively. It was found that CO₂ retains the original linear configuration on pristine Pt(111), similar to its isolated gas-phase state. In contrast, there are strong interactions between CO₂ molecule and the Ti₃O₆H₆/Pt(111) interface, with C atom strongly binding to the Pt atom underneath with a bond length of 2.02 Å and one O atom (O₂) attaching to the Ti atom with a shorter bond length of 1.96 Å. Such a strong bonding between CO₂ and Ti₃O₆H₆/Pt(111) interface results in a significant bending of CO₂ molecule from its originally linear form to an O—C—O angle of 125.02°, thus forming a tridentate configuration that facilitates its subsequent transformations. In addition, the strong interaction of CO₂ with the interface weakens the two C—O bonds of CO₂, leading to elongated C—O bonds (1.22 Å and 1.32 Å) from the original bond length of 1.18 Å in the isolated CO₂ molecule (Table S2, Supporting Information). The weakened C—O bonds and the formed bent CO₂ configurations indicate a remarkable activation of CO₂ molecule upon chemisorption at the interface, which is in contrast with the negligible activation of CO₂ on pristine Pt(111). This result agrees well with the observations in the field of thermochemical catalysis that CO₂ transformation is greatly enhanced with metal/oxide interface as compared to that with pure metal. The CO₂ activation mechanism at metal/oxide interface has a certain degree of similarity to that reported on individual metal oxide (e.g., TiO₂) with oxygen vacancies, in which one of the O atoms in CO₂ is coordinating to an under-coordinated Ti atom at the edge of the cluster (i.e., essentially an O vacancy).

The energetics associated with CO₂ adsorption on Pt(111) and Ti₃O₆H₆/Pt(111) surfaces were also calculated and analyzed in terms of the adsorption energy (E_{ad}) and deformation energy (E_{def}^{CO}^{₂}) (Table S2, Supporting Information). Here E_{ad} represents the net energy increased upon adsorption. E_{def}^{CO}^{₂} denotes the energy change from the distortion of a linear CO₂ molecule into a buckled configuration, correlating with the degree of CO₂ activation.⁷³ The E_{ad} and E_{def}^{CO}^{₂} of CO₂ adsorption at Ti₃O₆H₆/Pt(111) interface are −0.80 and 2.65 eV respectively, as compared with those of 4.44 eV and 0.01 eV on pristine Pt(111). The negative E_{ad} value implies the exothermic process of CO₂ adsorption at Ti₃O₆H₆/Pt(111) interface, while positive E_{ad} value indicates the unfavourable CO₂ adsorption on pristine Pt(111). In addition, the large positive value of E_{def}^{CO}^{₂} in the case of Ti₃O₆H₆/Pt(111) confirms that CO₂ is activated spontaneously at the interface, in strong contrast to the marginal value on pristine Pt(111). Experimentally, the amount of CO₂ adsorption capacity over Pt/GaN/n⁺-p Si and Pt—TiO₂/GaN/n⁺-p Si was tested by CO₂ adsorption-desorption measurements (FIG. S8, Supporting Information). The CO₂ adsorption amount over Pt—TiO₂/GaN/n⁺-p Si was 1.91 μmol cm⁻², which was 7 times higher than that of Pt/GaN/n⁺-p Si (0.27 μmol cm⁻²). As a comparison, the CO₂ adsorption amount on plain GaN/n⁺-p Si was 0.24 μmol cm⁻², indicating the low propensity of Pt for CO₂ chemisorption. The combined experimental and theoretical results explain well the different behaviors in the PEC studies that pristine Pt does not favor CO₂ reduction, while the construction of Pt/TiO₂ interface shows greatly enhanced activity for CO₂ reduction.

To further investigate the detailed bonding interaction between CO₂ and Ti₃O₆H₆/Pt(111) interface, the differential charge density (DCD) was examined, shown in FIG. 6. The differently shaded regions indicate electronic charge accumulation and depletion. Strong electronic coupling between CO₂ and the interface was evidenced by the electron charge density redistribution around the interfacial region. Notable electron accumulation near the O₂ atom in CO₂ and electron depletion around the neighboring Ti nucleus indicates an ionic-like Ti—O bonding, while the electron accumulation between Pt and C atoms suggests the formation of covalent Pt—C bonding. Overall, substantial electrons are transferred from the interface to CO₂ molecule, resulting in the formation of activated *CO₂⁻ anion and eventually the enhanced CO₂ reduction activity. Quantitative estimate of the electron transfer was studied by Bader charge analysis. It was found that CO₂ attracted 0.684 e from the substrate for CO₂ adsorption at the Ti₃O₆H₆/Pt(111) interface, as compared to 0.0263 e in the case of pristine Pt.

FIG. 6 also depicts side views of optimized configurations of CO₂ adsorbed on the (a) Pt(111) surface and (b) Ti₃O₆H₆/Pt(111) surface. (c) Differential charge density of CO₂ adsorbed at the Ti₃O₆H₆/Pt(111) interface. Regions of yellow and blue indicate electronic charge gain and loss, respectively. Isosurface contours of electron density differences were drawn at 0.002 e/Bohr3. (d) Calculated free energy diagrams for CO₂ reduction to CO on Pt(111) and Ti₃O₆H₆/Pt(111) surfaces at 0 V vs. RHE. The optimized structures for each step are also shown. To improve legibility, a break region was added from 0.25 to 3.75 on the Y axis due to the large energy barriers for the CO₂ reduction on Pt(111) surface. Pt: grey, Ti: blue, O: red, C: brown and H: white.

To gain insights into the selective CO evolution from CO₂ reduction at molecular level, DFT calculations were also performed to understand the reaction energetics of the CO₂→CO pathway. As suggested by previous studies,⁷⁶⁻⁷⁸ we considered the following reaction steps:

CO₂(g)+*+H⁺(aq)+e⁻→*COOH (1)

*COOH+H⁺(aq)+e⁻→*CO+H₂O(l) (2)

*CO→CO(g)+* (3)

where a lone asterisk (*) represents a surface adsorption site and * symbol before a molecule denotes a surface-bound species. FIG. 6 shows the calculated free energy diagram of CO₂ reduction on Pt(111) and Ti₃O₆H₆/Pt(111). On pristine Pt(111), the first step of CO₂ activation to form *COOH intermediate is highly endergonic with a free energy change (ΔG) of 5.08 eV, which is the rate-limiting step for the whole CO₂ reduction process. In contrast, on the Ti₃O₆H₆/Pt(111) interface, *COOH formation is exergonic owing to the strong binding to the interfacial sites, with C and O atoms in COOH binding to Pt(111) and Ti of Ti₃O₆H₆, respectively. Similarly, the strong binding and stabilization of *CO intermediates were also observed with cooperative interactions with both metal and oxide in the interface, resulting in the facile formation of *CO. The rate-limiting step in the Ti₃O₆H₆/Pt(111) system is the CO desorption, but with a much smaller free energy change of 0.88 eV as compared to 5.08 eV on pristine Pt(111). This result suggests that there are sites of different nature with complementary chemical properties in the metal/oxide interface that work in synergy to facilitate the CO₂ reduction into CO. In addition, the effects of the electrolyte and applied potential were considered in DFT calculations, similar conclusions were obtained.

Considering that H₂ product from proton reduction is the other important component in the syngas mixture besides CO, free energy diagrams were also calculated for H₂ evolution on pristine Pt(111) and Ti₃O₅H₆/Pt(111). Ti₃O₆H₆/Pt(111) showed a slightly lowered energy barrier than that on pristine Pt(111) by 0.06 eV. Considering that the uncertainty associated with DFT energy calculations is on the same order, the calculated energy barriers for hydrogen evolution reaction are comparable in the two cases. Recent studies have shown that the CO₂ reduction selectivity in competition with H₂ evolution is related to the difference between their two thermodynamic limiting potentials (denoted as U_{L}(CO₂)−U_{L}(H₂)). Therefore, the difference between limiting potentials for CO evolution from CO₂ reduction and H₂ evolution was calculated, Ti₃O₆H₆/Pt(111) displays a significant more positive value for U_{L}(CO₂)−U_{L}(H₂) than that on pristine Pt(111), indicating higher selectivity for CO₂ reduction to CO.

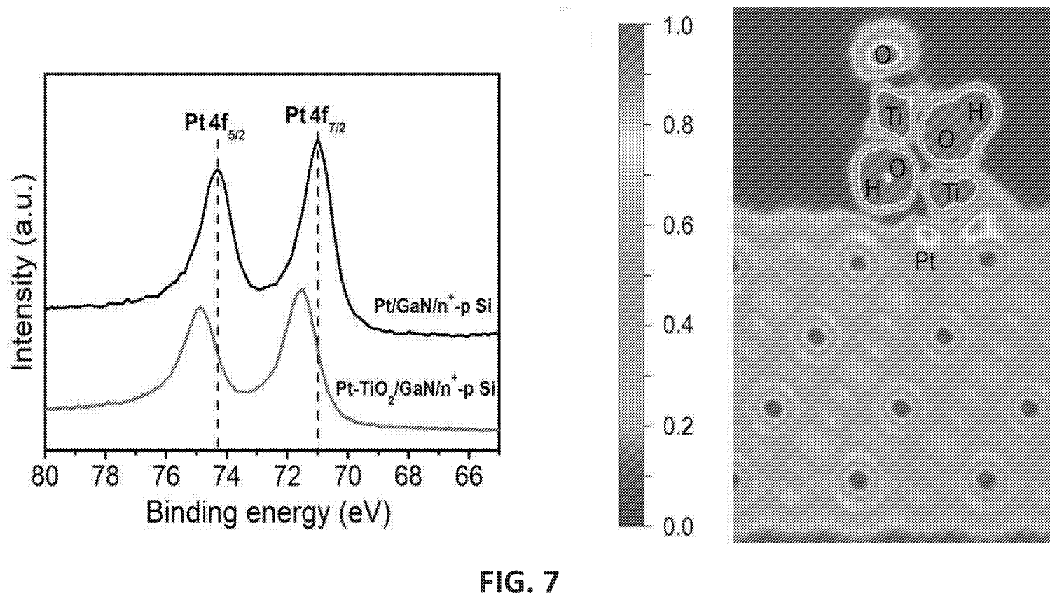

In addition to the important role of the metal/oxide interface in activating CO₂ and stabilizing the key reaction intermediates, the electronic modification of the Pt catalyst owing to the strong interaction between metal and oxide may also contribute to the selective CO₂ reduction into CO on Pt—TiO₂/GaN/n⁺-p Si photocathode. The electronic properties of Pt were evaluated using the peak energy of Pt 4f by X-ray photoelectron spectroscopy (XPS) analysis (FIG. 7). Compared to Pt/GaN/n⁺-p Si, a notable shift of ca. 0.5 eV to higher binding energy position was observed for Pt 4f in Pt—TiO₂/GaN/n⁺-p Si. This shift is less pronounced than the binding energy difference between Pt⁰ and Pt²⁺ in PtO (ca. 1.5 eV), indicating the presence of electron deficient Pt species (Ptⁿ⁺) in Pt—TiO₂/GaN/n⁺-p Si. A significant electronic modification by strong metal/oxide interaction is likely responsible for this change of Pt oxidation state. To confirm the strong interaction between the metal and oxide, the electron localized function (ELF) for Ti₃O₆H₆/Pt(111) system was calculated, as shown in FIG. 7. Topology analysis of ELF can effectively characterize the nature of different chemical bonding schemes, and has been used to estimate the degree of metal-support interactions. The ELF map of Ti₃O₆H₆/Pt(111) shows that there is a significant electron redistribution in the regions between Pt and Ti₃O₆H₆, indicating strong interactions between them. The strong interactions can modify the electronic property of Pt and hence enhance CO₂ reduction.

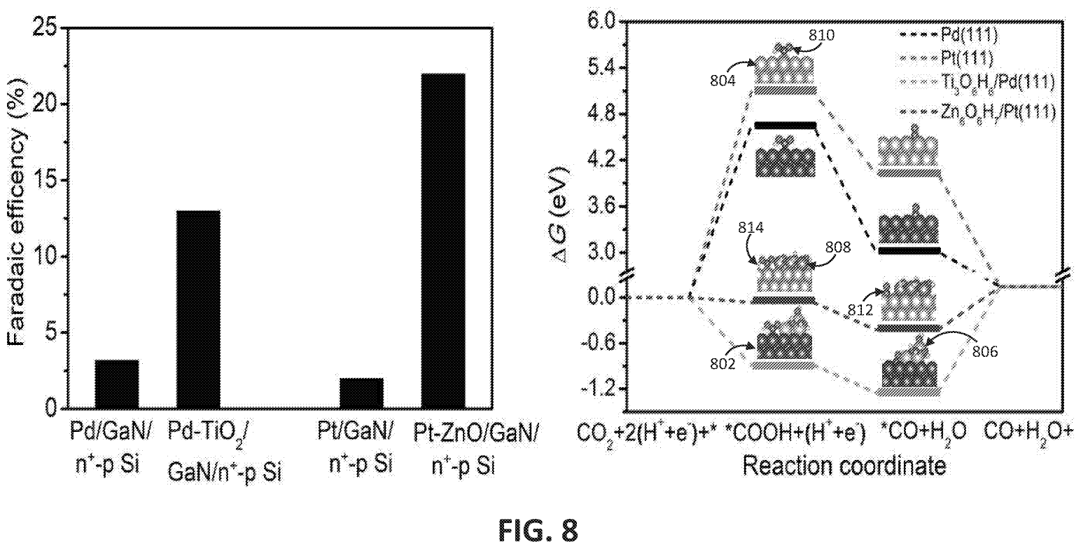

The foregoing analysis of the Pt—TiO2 interface may be generalized to other metal/oxide systems. By understanding the CO₂ activation and conversion at the Pt/TiO₂ interface on an atomic level, the findings may be extended to other metal/oxide systems. To show the generality, Pd—TiO₂/GaN/n⁺-p Si and Pt—ZnO/GaN/n⁺-p Si were synthesized by varying either metal or oxide components (see the Supporting Information). The chemical components and structures were confirmed by TEM and EDX analysis. By using ICP-AES analysis, the loading amounts of Pd and Ti in Pd—TiO₂/GaN/n⁺-p Si, Pt and Zn in Pt—ZnO/GaN/n⁺-p Si were determined to be 5.4 and 46.1, 4.7 and 39.1 nmol cm⁻², respectively. The FEs of CO for Pd—TiO₂/GaN/n⁺-p Si and Pt—ZnO/GaN/n⁺-p Si were measured and compared with Pd/GaN/n⁺-p Si and Pt/GaN/n⁺-p Si, respectively (FIG. 5a). The CO FEs of Pd—TiO₂/GaN/n⁺-p Si and Pt—ZnO/GaN/n⁺-p Si are four and eleven times higher than that with individual metal co-catalysts, similar to the trend observed in Pt—TiO₂/GaN/n⁺-p Si system. In addition, the free energy diagram of CO₂ reduction into CO were calculated to validate the experimental observations. Ti₃O₆H₆/Pd(111) and Zn₆O₆H₇/Pt(111) were used in the DFT calculations to describe the Pd/TiO₂ and Pt/ZnO interface, respectively. As seen in FIG. 8, Ti₃O₆H₆/Pd(111) and Zn₆O₆H₇/Pt(111) show a significantly lowered energy barrier than those on pristine Pd(111) and Pt(111). Similarly, it was found that the formation of *CO from CO₂ reduction via *COOH intermediate is a facile downhill process in the presence of metal/oxide interface, while the first step of CO₂ activation to form *COOH is highly endergonic on pure metal surface. Although quantitative differences exist between different systems, a similar qualitative trend indicates the critical role of metal/oxide interfaces in activating CO₂, and stabilizing the key reaction intermediates for facilitating CO production. The disclosed co-catalyst interfaces therefore provide a useful mechanism for enhancing CO₂ reduction performance, e.g., by tuning the compositions and structures of the metal/oxide interface.

FIG. 7 depicts (a) XPS of Pt 4f of Pt/GaN/n⁺-p Si and Pt—TiO₂/GaN/n⁺-p Si. (b) Electron localized function (ELF) of Ti₃O₆H₆/Pt(111). The probability of finding electron pairs varies from 0 (blue color) to 1 (red color).

FIG. 8 depicts (a) Faradaic efficiencies for CO of Pd/GaN/n⁺-p Si, Pd—TiO₂/GaN/n⁺-p Si, Pt/GaN/n⁺-p Si and Pt—ZnO/GaN/n⁺-p Si. The measurements were performed at +0.3 V vs. RHE for 100 min. (b) Calculated free energy diagrams for CO₂ reduction to CO on Pd(111), Pt(111), Ti₃O₆H₆/Pd(111) and Zn₆O₆H₇/Pt(111) surfaces at 0 V vs. RHE. The optimized structures for each step are also shown. To improve legibility, a break region was added from 0.25 to 2.75 on the Y axis due to the large energy barriers for the CO₂ reduction on Pd(111) and Pt(111) surface. In FIG. 8, the following elements are denoted with colors and reference numerals as follows—Pd: pine green (802), Pt: grey (804), Ti: blue (806), Zn: purple (808), O: red (810), C: brown (812) and H: white (814).

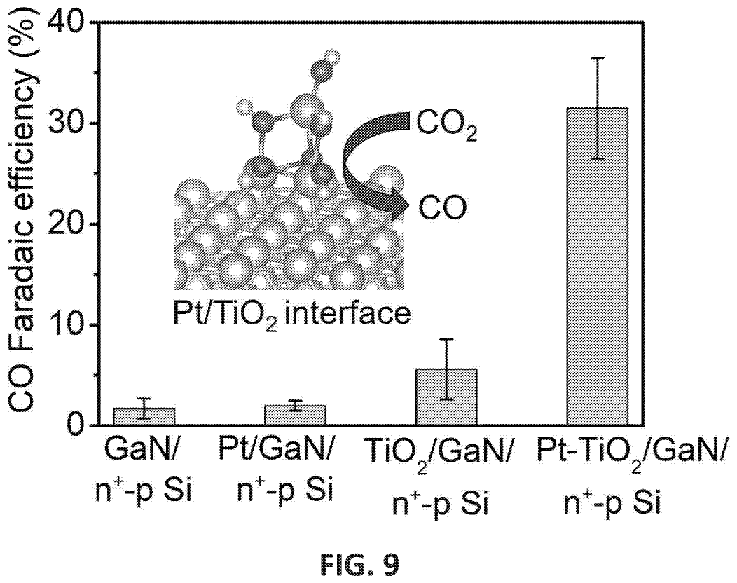

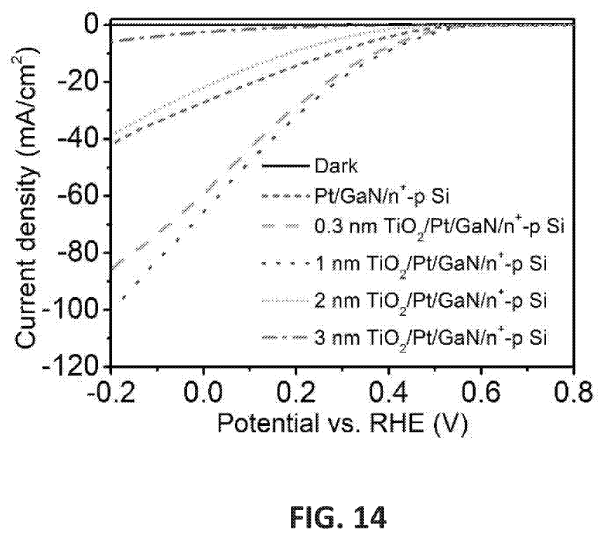

FIG. 9 depicts further FE data for an electrode having co-catalysts as described herein. The FE data is presented in comparison with the FE data for other electrodes. FIG. 10 is a plot of current density curves of an electrode having co-catalysts in accordance with one example. FIG. 11 is a plot of chronoamperometry data of an electrode having co-catalysts in accordance with one example at various applied potentials. FIG. 12 is a plot of partial current density for CO and H₂ for an electrode having co-catalysts in accordance with one example. FIG. 13 is a Tafel plot for CO and H₂ evolution for an electrode having co-catalysts in accordance with one example. FIG. 14 is a plot of current density curves for electrodes having co-catalysts in accordance with several examples having different oxide thicknesses. FIG. 15 is a plot of Faradaic efficiencies of electrodes having co-catalysts in accordance with several examples having different oxide thicknesses.

In summary, an efficient and stable CO₂ reduction system for syngas production with controlled composition, by employing a metal/oxide interface to activate inert CO₂ molecule and stabilize the key reaction intermediates. Using Pt/TiO₂ as an example, a benchmarking solar-to-syngas efficiency of 0.87% and a high turnover number of 24800 were achieved. Moreover, an example PEC system exhibited highly stable syngas production in the 10 h duration test. On the basis of experimental measurements and theoretical calculations, it was found that the synergistic interactions at the metal/oxide interface provide unique reaction channels that structurally and electronically facilitate CO₂ conversion into CO. The disclosed electrodes and systems may thus useful in realizing high-performance photoelectrochemical systems for selective CO₂ reduction.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. An electrode of a chemical cell, the electrode comprising:
a structure having an outer surface;
a plurality of catalyst particles distributed across the outer surface of the structure; and
a catalyst layer disposed over the plurality of catalyst particles and the outer surface of the structure;
wherein each catalyst particle of the plurality of catalyst particles comprises a metal catalyst for reduction of carbon dioxide (CO₂) in the chemical cell, and
wherein the catalyst layer comprises an oxide material for the reduction of carbon dioxide (CO₂) in the chemical cell.

2. The electrode of claim 1, wherein:
the substrate comprises a semiconductor material; and
the semiconductor material is configured to generate charge carriers upon absorption of solar radiation such that the chemical cell is configured as a photoelectrochemical system.

3. The electrode of claim 2, wherein:
the structure comprises a substrate and an array of conductive projections supported by the substrate;
the array of conductive projections defines the outer surface of the structure; and
the array of conductive projections are configured to extract the charge carriers generated in the substrate.

4. The electrode of claim 3, wherein each conductive projection of the array of conductive projections comprises a respective nanowire.

5. The electrode of claim 3, wherein each conductive projection of the array of conductive projections comprises a Group III-V semiconductor material.

6. The electrode of claim 1, wherein the structure is planar.

7. The electrode of claim 1, wherein the metal catalyst is platinum or palladium.

8. The electrode of claim 1, wherein the oxide material comprises titanium dioxide (TiO₂) or zinc oxide (ZnO).

9. The electrode of claim 1, wherein each catalyst particle of the plurality of catalyst particles is configured as a nanoparticle.

10. The electrode of claim 1, wherein each catalyst particle of the plurality of catalyst particles has a diameter falling in a range from about 2 nanometers to about 3 nanometers.

11. The electrode of claim 1, wherein the catalyst layer has a thickness falling in a range from about 0.3 nanometers to about 3 nanometers.

12. The electrode of claim 1, wherein the chemical cell is a thermochemical cell.

13. An electrochemical system comprising a working electrode configured in accordance with the electrode of claim 1, and further comprising:
a counter electrode;
an electrolyte in which the working and counter electrodes are immersed; and
a voltage source that applies a bias voltage between the working and counter electrodes;
wherein the bias voltage establishes a ratio of CO₂ reduction to hydrogen (H₂) evolution at the working electrode.

14. A photocathode for a photoelectrochemical cell, the photocathode comprising:
a substrate comprising a light absorbing material, the light absorbing material being configured to generate charge carriers upon solar illumination;
an array of conductive projections supported by the substrate, each conductive projection of the array of conductive projections being configured to extract the charge carriers from the substrate;
a plurality of catalyst particles distributed across each conductive projection of the array of conductive projections; and
a catalyst layer disposed over the plurality of catalyst particles and each conductive projection of the array of conductive projections;
wherein each catalyst particle of the plurality of catalyst particles comprises a metal catalyst for reduction of carbon dioxide (CO₂) in the electrochemical cell, and
wherein the catalyst layer comprises an oxide material for the reduction of carbon dioxide (CO₂) in the electrochemical cell.

15. The photocathode of claim 14, wherein the metal catalyst is platinum or palladium.

16. The photocathode of claim 14, wherein the oxide material comprises titanium dioxide (TiO₂) or zinc oxide (ZnO).

17. The photocathode of claim 14, wherein each catalyst particle of the plurality of catalyst particles is configured as a nanoparticle.

18. The photocathode of claim 14, wherein each conductive projection of the array of conductive projections comprises a respective nanowire.

19. A photoelectrochemical system comprising a working photocathode configured in accordance with the photocathode of claim 14, and further comprising:
a counter electrode;
an electrolyte in which the working photocathode and the counter electrode are immersed; and
a voltage source that applies a bias voltage between the working photocathode and the counter electrode;
wherein the bias voltage establishes a ratio of CO₂ reduction to hydrogen (H₂) evolution at the working electrode.

20. A method of fabricating an electrode of an electrochemical system, the method comprising:
depositing a plurality of catalyst particles across an outer surface of a structure of the electrode, each catalyst particle of the plurality of catalyst particles comprising a metal catalyst for reduction of carbon dioxide (CO₂) in the electrochemical system; and
forming a catalyst layer over the plurality of catalyst particles and the outer surface of the structure, the catalyst layer comprising an oxide material for the reduction of carbon dioxide (CO₂) in the electrochemical system.

21. The method of claim 20, wherein depositing the plurality of catalyst particles comprises implementing a photodeposition process, the photodeposition process being configured to deposit nanoparticles of the metal catalyst.

22. The method of claim 20, wherein forming the catalyst layer comprises implementing an atomic layer deposition (ALD) process, the ALD process being configured to deposit a nanolayer of the oxide material.

23. The method of claim 20, further comprising growing an array of nanowires on a semiconductor substrate to form the structure of the electrode and define the outer surface.
